(19) United States
(12) Patent Application Publication
(10) Pub. No.: US 2026/0309556 A1
(43) Pub. Date: Oct. 8, 2026

(54) CAPACITIVE SWITCH STRUCTURE FOR NONDISCRETE, TACTILE AND NONTACTILE SWITCHES WITH CUSTOMIZABLE MINIMUM ACTIVATION THRESHOLDS

(71) Applicants: NITTO BEND TECHNOLOGIES, INC., Farmington, UT (US); NITTO DENKO CORPORATION, Kita-ku, Osaka (JP)

(72) Inventors: TOSHIHIKO OMOTE, San Diego, CA (US); BENEDICTO DELOS SANTOS, San Diego, CA (US); JOHN BORTELL, Livonia, MI (US); JUMA BELKNAP, Reedley, CA (US)

(73) Assignees: NITTO BEND TECHNOLOGIES, INC., Farmington, UT (US); NITTO DENKO CORPORATION, Kita-ku, Osaka (JP)

(21) Appl. No.: 19/122,635

(22) PCT Filed: Oct. 18, 2023
(86) PCT No.: PCT/US2023/035385

§ 371 Date: Apr. 18, 2025

(51) Int. Cl. G01L 1/14; H03K 17/96

(52) U.S. Cl. CPC G01L 1/142; H03K 17/962; H03K 2217/96071

(57) ABSTRACT

Disclosed embodiments include a strain sensor having a flexible sensor layer, the flexible sensor layer including a dielectric layer, a first electrode layer, and a second electrode layer, the first and second electrode layers disposed on opposite sides of the dielectric layer, and a first deformable layer located on either the first or second electrode layers and wherein a deformation of the first deformation layer greater than a predetermined amount is sufficient to deform the flexible sensor layer and generate an impulse signal indicating deformation above a predetermined threshold. Embodiments may include incorporating the strain sensor into a capacitive button or switch.

### CROSS-REFERENCE TO RELATED APPLICATIONS

This application, under 35 U.S.C. § 119, claims the benefit of U.S. Provisional Patent Application Ser. No. 63/379,958 filed on Oct. 18, 2022, and entitled “Capacitive Switch Structure For Non-Discrete, Tactile and Nontactile Switches With Customizable Minimum Activation Thresholds,” the contents of which are hereby incorporated by reference herein.

### FIELD OF THE DISCLOSURE

This disclosure relates generally to capacitive switches for use in electronic circuitry and the like. More particularly this disclosure relates to capacitive switches for non-discrete tactile and nontactile switches with customizable activation thresholds.

### BACKGROUND

Capacitive and resistive sensors are known. For example, surface capacitive sensing and projected capacitive sensing are existing touch sensing techniques. In surface capacitive sensing, an insulator is used with a conductive coating on one side of its surface. On top of this conductive coating, a thin layer of insulator is applied. Current is applied to all the corners of the conductive coating. When an external conductor like a human finger, a stylus, or the like comes in contact with the surface, a capacitance is formed between them and draws more current from the corners. The current at each corner is measured and their ratio will determine the position of the touch on the surface.

In projected capacitive sensing, the whole surface is not charged, but an X-Y grid of conductive material is placed between two insulating materials. The grid is often made of copper (Cu) or gold (Au) on a printed circuit board (PCB) or Indium-Tin-Oxide on glass. An integrated circuit (IC) is used to charge and monitor the grid. When a charge is pulled by external conducting object like a finger(s), stylus, or the like, from an area on the grid, the IC calculates the location of the object on the touch surface. Touch sensors, made of projective capacitive technology can be used to sense a finger that is not touching its surface. They act as near proximity sensors.

A resistive touch sensor consists of two conductive layers separated by small spacer dots. The bottom layer is made up of either glass or film and the top layer is made up of film. The conductive material is coated with metallic film generally Indium-Tin-Oxide and is transparent in nature. A voltage is applied across the surface of the conductor. When any probe like a finger, stylus, pen, etc., is used to apply pressure on the top film of the sensor, it activates the sensor. When ample pressure is applied, the top film flexes inward and makes contact with the bottom film. This results in voltage drop and the point of contact creates a voltage divider network in the X-Y directions. This voltage and the changes in the voltage are detected by a controller and calculate the position of the touch where the pressure is applied based on the X-Y coordinates of the touch.

Additionally, switches are known. For example, both tactile and nontactile dome switches are known to typically rely on creating a direct conductivity path when the dome is depressed. This results in a switch that switches between on and off states with nothing in between. Some dome switches may also include capacitive sensors such as U.S. Pat. No. 8,963,036, titled “Capacitive Dome Switch” and which is incorporated herein by reference.

Spring sensor button sensors also exist. These are typically similar to capacitive dome switches but employ a spring. When the spring is compressed, the windings get closer to each other and the capacitance of the spring changes. There is usually a ground connection on the PCB surface for the spring to interact with. For example, U.S. Pat. No. 4,584,444, titled “Keyboard Switch,” discloses an example capacitive spring switch and is herein incorporated by reference. Other switches also exist.

In some applications and environments it is desirable for a sensor to detect some types of “touches” or impacts and ignore others. The above-described existing sensors and switches do not easily lend themselves or are incapable of such threshold customization.

Further, existing switches or detectors are typically not made entirely from soft materials. Thus, the switch or detector is perceivable or sensible when embedded in soft surfaces which can be undesirable.

Additionally, some applications and environments require sensing of local touches or impacts over a large surface area. Again, the above-described existing sensors and switches do not easily lend themselves or are incapable of such large area detection. Other drawbacks, inconveniences, inefficiencies, and issues also exist with current systems and methods.

### SUMMARY

Accordingly, disclosed embodiments address the above, and other, drawbacks, inconveniences, inefficiencies, and issues with current systems and methods. Other advantages and efficiencies of disclosed systems and methods also exist.

As used herein, “flexible,” “extensible,” “compliant,” and the like are used somewhat interchangeably and all mean that some amount of flexing, stretching, compression, twisting, bending, or the like, exists for the described embodiment.

Disclosed embodiments include a strain sensor element for disposal to a desired location. The sensor element including a sensor sub-element, the sensor sub-element having a planar surface and comprising a dielectric layer, a first ground electrode layer, and a second ground electrode layer, the first and second ground electrode layers disposed on opposite sides of the dielectric layer, said first and second ground layers and the dielectric layer defining a first and second air gaps therebetween. The sensor element further including a deformation layer, wherein the deformation layer and the sensor sub-element define a third air gap, or more compressible region, therebetween and wherein when the deformation of the deformation layer is greater than a predetermined amount and sufficient to transcend the third air gap and deform the planar surface of the sensor sub-element, increasing the surface area of the sensor sub-element and generating an impulse signal indicating deformation above a desired threshold. In some embodiments the predetermined amount of deformation of the deformation layer is substantially 5 mm.

In some embodiments the defined third air gap is at least 4.5 mm between the deformation layer and the second ground layer. In further embodiments the third air gap may be a hermitically sealed air bag.

In some embodiments the sensor element also includes Faraday cage element.

In some embodiments the dielectric layer comprises air, foams, films, and gels comprised of Silicone, Urethane, thermoplastic elastomer (TPE), fluoropolymer, and other deformable and/or elastomeric materials.

In some embodiments the sensor element includes an indicator, the indicator in electrical communication with the first and second ground electrodes, wherein the impulse signal generated by the strain sensor provides an indication of deformation greater than the desired threshold.

In some embodiments the sensor element includes air, foams, films, and gels comprised of Silicone, Urethane, thermoplastic elastomer (TPE), fluoropolymer, and other deformable and/or elastomeric materials, wherein the foam material layer is disposed between the first ground layer and the desired location. In further embodiments the foam material has a hardness factor less than the deformation layer and the support plate is less rigid than the foam material layer and the deformation layer. In some embodiments the sensor sub-element is more compressible than the deformation layer and the foam material layer. In some embodiments the foam material layer includes an adhesive layer for adhering the strain sensor element to the desired location.

In some embodiments the sensor element includes stiffeners disposed between at least one of the deformation layer and the third air gap, the third air gap and the sensor sub-element or the sensor sub-element and the foam material layer.

In some embodiments the sensor element is disposed between a battery pack floor structure and the surrounding environment.

Also disclosed are embodiments of a button for selective activation by a user, the button incorporating the sensor element as disclosed herein and wherein the deformable layer is disposed for contact and deformation by the user for selective activation.

Other embodiments also exist.

### BRIEF DESCRIPTION OF THE DRAWINGS

FIG. 1 is a schematic cross-sectional view of a stack of layers to form a compliant sensor system in accordance with disclosed embodiments.

FIG. 2 is a schematic illustration of a basic sensor element structure in accordance with disclosed embodiments.

FIG. 3 is a schematic illustration of an application of sensor elements in an EV battery module in accordance with disclosed embodiments.

FIG. 4 is a schematic illustration of an application of a sensor element in an EV battery module in accordance with disclosed embodiments.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the spirit and scope of the invention as defined by the appended claims.

### DETAILED DESCRIPTION

It should be understood that, as used herein, the terms “vertical,” “horizontal,” “lateral,” “upper,” “lower,” “top,” “bottom,” “left,” “right,” “inner,” “outer,” etc., can refer to relative directions or positions of features in the disclosed devices and/or assemblies shown in the Figures. For example, “upper” or “uppermost” can refer to a feature positioned closer to the top of a page than another feature. These terms, however, should be construed broadly to include devices and/or assemblies having other orientations, such as inverted or inclined orientations where top/bottom, over/under, above/below, up/down, and left/right can be interchanged depending on the orientation.

As discussed above, in some applications and environments it is desirable for a sensor to detect some types of “touches” or impacts and ignore others. Additionally, some applications and environments require sensing of local touches or impacts over a large surface area. For example, in an embodiment directed to an impact sensor for an electric vehicle (EV) battery pack it may be desirable to be able to sense if damage has occurred to the road-facing surface of the pack by stone impacts, driving over curbs, and the like, and sensing needs to be over a relatively large surface area. An impact sensor could help manage the safety/maintenance situation before additional damage occurs, such as rupture of coolant lines near the EV battery pack allowing coolant to leak into the pack, potentially causing electrical shorts or the like. However, if an impact was small, or otherwise expected, it need not be sensed as there would likely be no worrisome damage.

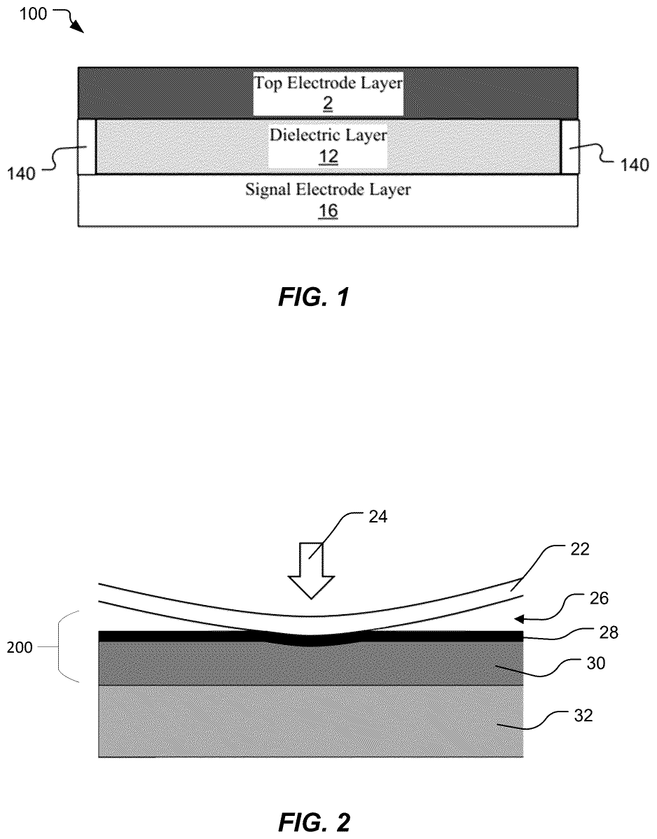

FIG. 1 is a schematic cross-sectional view of a stack 100 of layers to form a compliant sensor system. As shown, dielectric layer 12, is in between top electrode layer 2 and signal electrode layer 16. As also indicated schematically, perimeter electrode 140 electrically connects top electrode layer 2 and signal electrode layer 16. Other configurations are also possible.

In some embodiments, top electrode layer 2 may comprise an elastomeric layer (e.g., silicone) with conductive particles (e.g., nano-particles, such as carbon black, nickel nano-strands, silver nano-particles, graphene nano-platelets, graphene-oxides, or the like) integrated within. While shown in FIG. 1 as a continuous layer, top electrode layer 2 may also be “hatched” or otherwise non-continuous. Top electrode layer 2 may also include a printed circuit board (PCB) interface and a number of conductive trace pads for attaching a PCB, sensor traces, or other electronics, for operation and control of the sensor system.

In some embodiments dielectric layer 12 may comprise an elastomeric material (e.g., silicone) and, as desired, may have some conductive material integrated within depending upon, among other things, the intended amount of permittivity, or the like. While not drawn rigorously to scale, in some embodiments dielectric layer 12 is sized to be slightly smaller than top electrode layer 2 to leave a perimeter edge of top electrode layer 2 uncovered by dielectric layer 12 and allow electrical contact with perimeter electrode 140 as disclosed below.

In some embodiments signal electrode layer 16 may comprise an elastomeric material (e.g., silicone) with conductive material (e.g., nano-particles, such as carbon black, nickel nano-strands, silver nano-particles, graphene nano-platelets, graphene-oxides, or the like) confined to sensor regions, traces, and perimeter electrode 140. A number of sensor regions may be distributed throughout the layer 16. Sensor regions may comprise regions of electrically conductive material. Sensor regions are electrically in communication with traces that are printed with signal electrode layer 16. As shown, embodiments of signal electrode layer 16 may include a perimeter electrode 140 that electrically connects to top electrode layer 2 to, among other things, provide electrical isolation for the entire sensor system. Other configurations are also possible.

FIG. 2 is a schematic illustration of a basic sensor element 200 structure in accordance with disclosed embodiments. As illustrated schematically an outer plate 22 may be subjected to a deformation force 24. For example, in an EV battery embodiment outer plate 22 may comprise a protective cover for the EV battery and deformation force 24 may be due to impact with a road surface. In some embodiments an air gap 26 or other compressible layer may be between outer plate 22 and a sensor layer 28. Sensor layer 28 may comprise a single-axis complaint sensor as described above with reference to FIG. 1. A dielectric layer may cover the exterior surface of the sensor layer 28. An additional compressible layer 30 (e.g., foam, soft rubber, or the like) may be on the other side of sensor layer 28. Sensor element 200 may be mounted on support surface 32, e.g., a wall or floor of an EV battery or the like.

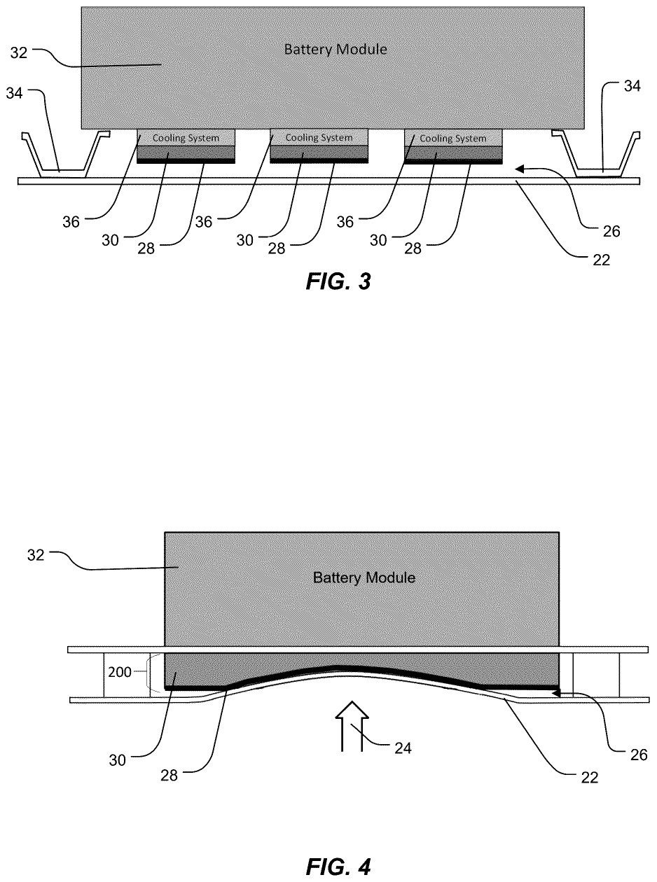

FIG. 3 is a schematic illustration of an application of sensor elements 200 in an EV battery module 32 in accordance with disclosed embodiments. As illustrated outer plate 22 may protect the bottom of battery module 32 and be supported and/or reinforced with appropriate supports 34 and the distance between these supports will also influence the sensing resolution and deformation characteristics of outer plate 22. In some embodiments a cooling system 36 (e.g., coils, tubing, etc., with liquid coolant or the like) may be provided as part of the system. As also shown a plurality of sensor elements (each comprising a sensor layer 28 and a compressible layer 30) may be mounted to the cooling system 36 to sense for any deformation of support plate 22 sufficient to be of concern as potential damage to cooling system 36 or battery module 32. As also shown for this embodiment an air gap 26 may be included between sensor layer 28 and support plate 22. As will be apparent to those of ordinary skill in the art having the benefit of this disclosure, components such as outer plate 22, battery module 32, and the like may be existing parts of other devices and need not be provided as part of sensor elements 200. Likewise, other configurations are also possible.

FIG. 4 is a schematic illustration of an application of a sensor element in an EV battery module in accordance with disclosed embodiments. In this embodiment a single, larger surface area sensor element 200 is used to substantially cover the bottom surface of the battery module 32. As represented schematically a deformation force 24 sufficient to deform outer plate 22 and consequently deform sensor element 200 will indicate an impact event. The combination of thickness and material properties for the outer plate 22, air gap (or additional compressible layer) 26, and compressible layer 30 may be optimized for specific sensing cases, such as, but not limited to, sensing impact due to vehicle driving events or sensing finger pressure on a button, or the like.

Furthermore, depending upon application, sensing needs, sensing environment, and the like, sensor element 200 components may vary. For example, outer plate 22 may be rigid (e.g., a metal plate), flexible (e.g., a rubber sheet), or semi-rigid/semi-flexible. The higher the flexural modulus and thickness of the given outer plate 22 material, the higher the minimum load/impact sensing threshold will be. In button/switch applications, outer plate 22 may give the typical tactile feel to the button's initial engagement.

In general, air gap (or other compressible layer) 26 should be more compressible than outer plate 22 and compressible layer 30. In some embodiments air gap (or other compressible layer) 26 may be a hermetically sealed air pouch or the like.

As discussed above embodiments of sensor layer 28 may contain a signal electrode and ground electrode with integrated Faraday cage. The mechanical properties of the sensor layer 28 may also be varied according to sensing needs and environment.

As noted above, compressible layer 30 is typically more compressible than outer plate 22 and support layer 32 and less compressible than air gap (or other compressible layer) 26. Compressible layer 30 may comprise soft rubber, foams, or the like.

Embodiments of support surface 32 may vary according to application and environment as well and is generally assumed to have little or no deflection and may be generally stiffer than the rest of the structure.

As those of ordinary skill in the art having the benefit of this disclosure will understand, the combined mechanical properties/thickness of outer plate 22 and air gap (or other compressible layer) 26 will typically determine the minimum sensing threshold. Likewise, if compressible layer 30 is more rigid than the outer plate 22 and the support surface is more rigid than both the outer plate 22 and the compressible layer, then sensor element may not allow the sensor layer 28 to strain in an easily calculable fashion (i.e., it would essentially be pinched between two hard surfaces). Similarly, if the outer plate 22 is deformed all the way to the support layer 32, further deformation may be inaccurately measured.

Furthermore, other than the conductive layers inside the sensing layer 28, all of the other components (i.e., 22, 26, 30, 32) may comprise either dielectric or conductive materials, chosen only based on a specific application's deformation characteristics and sensing requirements.

In some embodiments stiffeners could be locally positioned between any of outside plate 22 and air gap (or other compressible layer) 26, air gap (or other compressible layer) and sensor layer 28, or sensor layer 28 and compressible layer 30 to affect the deformation characteristics or sensing resolution. Likewise, employing ribs, varied thickness, or being embossed may provide a similar effect as having a stiffener between components.

Additionally, while only one sensing layer 28 is shown in the figures, if more accuracy or resolution is needed, then additional sensing layers 28 and compressible layers 30 may be added.

For button switch embodiments (e.g., FIG. 2) all of the component materials could be flexible, so they can be embedded into soft surfaces for seamlessly integrated nonmechanical Human-Machine Interface (HMI) purposes. The button could also have non-discrete sensing abilities once a minimum force/pressure is reached, based on the underlying capacitive sensor's abilities. For button embodiments it may also be desirable to include a graphic overlay indicating each button's purpose on the outer plate 22 or the like. The graphic overlay may also include embossed domes whose mechanical properties need to be considered for the final application. Other embodiments are also possible.

Although various embodiments have been shown and described, the present disclosure is not so limited and will be understood to include all such modifications and variations that would be apparent to one skilled in the art.

What is claimed is:

1. A strain sensor comprising:
a flexible sensor layer, the flexible sensor layer comprising a dielectric layer, a first electrode layer, and a second electrode layer, the first and second electrode layers disposed on opposite sides of the dielectric layer; and
a first deformable layer located on either the first or second electrode layers and wherein a deformation of the first deformation layer greater than a predetermined amount is sufficient to deform the flexible sensor layer and generate an impulse signal indicating deformation above a predetermined threshold.

2. The strain sensor of claim 1 wherein the predetermined amount of deformation of the first deformation layer is substantially 5 mm.

3. The strain sensor of claim 1 further comprising:
a second deformable layer located on an opposite side of the flexible sensor layer from the first deformable layer.

4. The strain sensor of claim 3 wherein either the first or second deformable layer may be a sealed air bag.

5. The strain sensor of claim 1 further comprising a Faraday cage element enclosing the flexible sensor layer.

6. The strain sensor of claim 1 wherein the dielectric layer comprises air, foams, films, and gels comprised of Silicone, Urethane, thermoplastic elastomer (TPE), fluoropolymer, and other deformable and/or elastomeric materials.

7. The strain sensor of claim 1 wherein the first and second electrode layers comprise air, foams, films, and gels comprised of Silicone, Urethane, thermoplastic elastomer (TPE), fluoropolymer, and other deformable and/or elastomeric materials.

8. The strain sensor of claim 1 further comprising:
an indicator in electrical communication with the first and second electrode layers, wherein the impulse signal generated by the flexible sensor layer activates the indicator to indicate a deformation greater than the predetermined threshold.

9. The strain sensor of claim 1 wherein the flexible sensor layer has a hardness factor less than the first deformable layer.

10. The strain sensor of claim 1 wherein the flexible sensor layer is more compressible than the first deformable layer.

11. The strain sensor of claim 1 further comprising an adhesive layer for adhering the strain sensor to a desired location.

12. The strain sensor of claim 1 further comprising:
one or more stiffeners disposed between the first deformable layer and the flexible sensor layer.

13. The strain sensor of claim 3 further comprising:
one or more stiffeners disposed between at least one of the first deformable layer and the flexible sensor layer and the second deformable layer and the flexible sensor layer.

14. A capacitive switch comprising:
a deformable outer plate;
a first compressible layer disposed on one side of the deformable outer plate;
a compliant capacitive sensor layer disposed on the opposite side of the first compressible layer from the deformable outer plate; and
a second compressible layer disposed on the opposite side of the compliant capacitive sensor layer from the first compressible layer.

15. The capacitive switch of claim 13 wherein a deformation of the deformable outer plate greater than a predetermined amount is sufficient to deform the first compressible layer and the compliant capacitive sensor layer and generate a signal indicating deformation above a predetermined threshold.

16. The capacitive switch of claim 13 wherein the first compressible layer comprises an air gap.

17. The capacitive switch of claim 13 wherein the first compressible layer is more compressible than the deformable outer plate and the second compressible layer.

18. The capacitive switch of claim 13 wherein the compliant capacitive sensor is more compressible than the first compressible layer and the second compressible layer.
